(19) United States
(12) Patent Application Publication
(10) Pub. No.: US 2012/0112364 A1
(43) Pub. Date: May 10, 2012

(54) WIRING STRUCTURE OF SEMICONDUCTOR DEVICE

(75) Inventor: Jin-man Chang, Suwon-si (KR)

(73) Assignee: SAMSUNG ELECTRONICS CO., LTD., Suwon-si (KR)

(21) Appl. No.: 13/238,632

(22) Filed: Sep. 21, 2011

(30) Foreign Application Priority Data
Nov. 4, 2010 (KR) 10-2010-0109255

(51) Int. Cl. H01L 23/52

(52) U.S. Cl. 257/775; 257/E23.141

(57) ABSTRACT

A wiring structure may include a first wiring having a first width that extends in a first direction, and a second wiring intersecting the first wiring, the second wiring extending in a second direction and having a second width that is equal to or less than the first width. Furthermore, the first wiring may have a third width that is smaller than the first width and the second wiring may have a fourth width that is smaller than the second width. Portions of the first and second wirings having the third and fourth widths may extend from an intersecting region in which the first wiring and the second wiring intersect each other.

### CROSS-REFERENCE TO RELATED APPLICATIONS

This application claims priority under 35 U.S.C. §119 to Korean Patent Application No. 10-2010-0109255, filed on Nov. 4, 2010, in the Korean Intellectual Property Office (KIPO), the disclosure of which is incorporated herein in its entirety by reference.

### BACKGROUND

1. Field

Example embodiments of inventive concepts relate to a wiring structure of a semiconductor device, and more particularly, to a wiring structure of a semiconductor device including intersecting wirings.

2. Description of the Related Art

As semiconductor devices are highly integrated, a design rule thereof is reduced. Thus, it becomes more difficult to perform a process of forming wirings and contact plugs, and the importance of the process of forming wires and contact plugs increases. Aluminum (Al) having excellent electrical conductivity is mainly used as a wiring material. Recently, copper (Cu) that has excellent electrical conductivity and low resistance and solves a problem about resistive-capacitive (RC) signal delay in a high-speed operating device is widely used as the wiring material. In general, when patterns are formed by using Cu as the wiring material, a damascene process of forming engraved wiring patterns in an insulating layer and then filling Cu in the engraved wiring patterns is used.

### SUMMARY

In accordance with example embodiments, a wiring structure of a semiconductor device may include a first wiring having a first width, the first wiring extending in a first direction, and a second wiring electrically connected to the first wiring, the second wiring having a second width that is equal to or less than the first width, the second wiring extending in a second direction. In example embodiments the first wiring and the second wiring may connect at an intersecting region, the first wiring may have a first portion extending from the intersecting region in the first direction, the second wiring may have a second portion extending from the intersection region in the second direction, the first portion may have a third width that is smaller than the first width, and the second portion may have a fourth width that is smaller than the second width.

In accordance with example embodiments, a wiring structure of a semiconductor device may include an intersecting region, a first wiring extending from the intersecting region in a first direction and having a first width, a second wiring extending from the intersecting region in a second direction and having a second width that is equal to or smaller than the first width. In example embodiments, the first wiring has a third width that is smaller than the first width along a length from the intersecting region and the second wiring has a fourth width that may be smaller than the second width along a length from the intersecting region.

In accordance with example embodiments, a wiring structure of a semiconductor device may include an intersecting region, a first wiring extending from the intersecting region, the first wiring including a first portion adjacent to the intersection region and a second portion extending from the first portion, the first portion having a first width and the second portion having a second width which is larger than the first width, the first and second portions extending in a first direction, and a second wiring extending from the intersecting region, the second wiring including a third portion adjacent to the intersection region and a fourth portion extending from the first portion, the third portion having a third width and the fourth portion having a fourth width which is larger than the third width, the third and fourth portions extending in a second direction. In example embodiments, a length of a largest straight line from among lines connecting two arbitrary points on the intersecting region is about 0.8 to about 1.2 times the second width and the fourth width.

In accordance with example embodiments, a wiring structure of a semiconductor may include a first wiring having a first width and extending in a first direction, and a second wiring intersecting the first wiring, extending in a second direction and having a second width that is equal to or less than the first width. In example embodiments each of the first wiring and the second wiring has each of a third width that is smaller than the first width and a fourth width that is smaller than the second width with respect to a length from an intersecting region in which the first wiring and the second wiring intersect each other. In example embodiments, the length may or may not be predetermined.

The intersecting region may be a closed curve defined by extending the first wiring and the second wiring to the third width and the fourth width, respectively.

The third width and the fourth width may be determined in such a way that a length of the largest straight line from among lines for connecting two arbitrary points on the closed curve forming the intersecting region is 0.8 to 1.2 times of a dimension of the first width.

Each of the third width and the fourth width may have a dimension obtained by reducing each of the first width and the second width by the same ratio.

Each of the third width and the fourth width may have a dimension that is 0.7 to 0.9 times of each of the first width and the second width.

The first direction and the second direction may be parallel to each other, and the first width and the second width may be the same as each other.

The length may be a dimension that is equal to or greater than 0.3 times of the second width.

The length may be a dimension that is equal to or less than 10 times of the first width.

Each of the first wiring and the second wiring may include one or more bending portions, which are respectively formed between the first width and the third width and between the second width and the fourth width.

When a number of the bending portions is two, the bending portions may be disposed in a straight line perpendicular to the first wiring and the second wiring on both side surfaces of the first wiring and the second wiring.

When a number of the bending portions is one, the bending portion may be disposed on one side surface of the first wiring or the second wiring at both side surfaces of the first wiring or the second wiring in a state where the intersecting region is formed between the first wiring and the second wiring.

The first wiring or the second wiring may extend from the intersecting region only in a one direction.

The length may be a first length and a second length that is smaller than the first length on both side surfaces that face the third width of the first wiring and the fourth width of the second wiring.

A sum of the second length and a length in which the first wiring or the second wiring extends to the intersecting region, may be equal to the first length.

The first direction and the second direction may be parallel to each other, and the intersecting region may include a vertical connection portion that connects the first wiring and the second wiring each other and is perpendicular to the first direction and the second direction, and a region in which an extension line of the vertical connection portion and the first and second wirings intersect one another.

The vertical connection portion may have a width that is equal to the third width or the fourth width.

According to another aspect of the inventive concepts, there is provided a wiring structure of a semiconductor device. In example embodiments of the inventive concepts, the wiring structure may include an intersecting region, a first wiring extending from the intersecting region in a first direction and having a first width, and a second wiring extending from the intersecting region in a second direction and having a second width that is equal to or smaller than the first width. In example embodiments each of the first wiring and the second wiring has a third width that is smaller than the first width and a fourth width that is smaller than the second width with respect to a length from the intersecting region.

The third width and the fourth width may be determined in such a way that a length of a straight line for connecting two arbitrary points of the intersecting region has a dimension that is equal to or less than a dimension of the first width.

The length may be a dimension that is equal to or greater than 0.3 times of a dimension of the second width and is equal to or less than 10 times of a dimension of the first width.

According to another aspect of the inventive concepts, there is provided a wiring structure of a semiconductor device. In example embodiment of the inventive concepts, the wiring structure may include two or more wirings that intersect each other, wherein the wirings include a region having a width that is smaller than widths of the wirings with respect to a length from an intersecting region in which the wirings intersect each other. In example embodiments of the inventive concepts the length may or may not be predetermined.

### BRIEF DESCRIPTION OF THE DRAWINGS

Example embodiments of the inventive concepts will be more clearly understood from the following detailed description taken in conjunction with the accompanying drawings in which:

FIG. 1 is a plan view of a wiring structure of a semiconductor device, according to example embodiments of the inventive concepts;

FIG. 2 is a plan view of a wiring structure of a semiconductor device, according to example embodiments of the inventive concepts;

FIGS. 3A through 3E are plan views of wiring structures of semiconductor devices, according to example embodiments of the inventive concepts;

FIGS. 4A through 4E are plan views of wiring structures of semiconductor devices, according to example embodiments of the inventive concepts;

FIGS. 5A through 5C are plan views of wiring structures of semiconductor devices, according to example embodiments of the inventive concepts;

FIGS. 6A through 6C are plan views of wiring structures of semiconductor devices, according to example embodiments of the inventive concepts;

FIGS. 7A and 7B are plan views of wiring structures of semiconductor devices, according to example embodiments of the inventive concepts;

FIGS. 8A through 8E are cross-sectional views for explaining a method of fabricating a wiring structure of a semiconductor device, according to example embodiments of the inventive concepts;

FIGS. 9A and 9B are electron microscope photos for illustrating a wiring structure of a semiconductor device, according to example embodiments of the inventive concepts;

FIG. 10 is a flowchart illustrating a layout method of forming a wiring structure of a semiconductor device, according to example embodiments of the inventive concepts;

FIG. 11 is a schematic view of a memory card including a semiconductor device, according to example embodiments of the inventive concepts; and

FIG. 12 is a schematic view of a system including a semiconductor device, according to example embodiments of the inventive concepts.

### DETAILED DESCRIPTION OF THE EMBODIMENTS

Example embodiments will be described more fully hereinafter with reference to the accompanying drawings, in which example embodiments are shown. The present invention may, however, be embodied in many different forms and should not be construed as limited to example embodiments as set forth herein. Rather, example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers that may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made in detail to example embodiments which are illustrated in the accompanying drawings. However, the inventive concepts are not limited to example embodiments illustrated hereinafter, and example embodiments herein are rather introduced to provide easy and complete understanding of the scope and spirit of the inventive concepts. In the drawings, the thicknesses of layers and regions are exaggerated for clarity.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes may be not intended to illustrate the actual shape of a region of a device and are not intended to limit the scope of example embodiments.

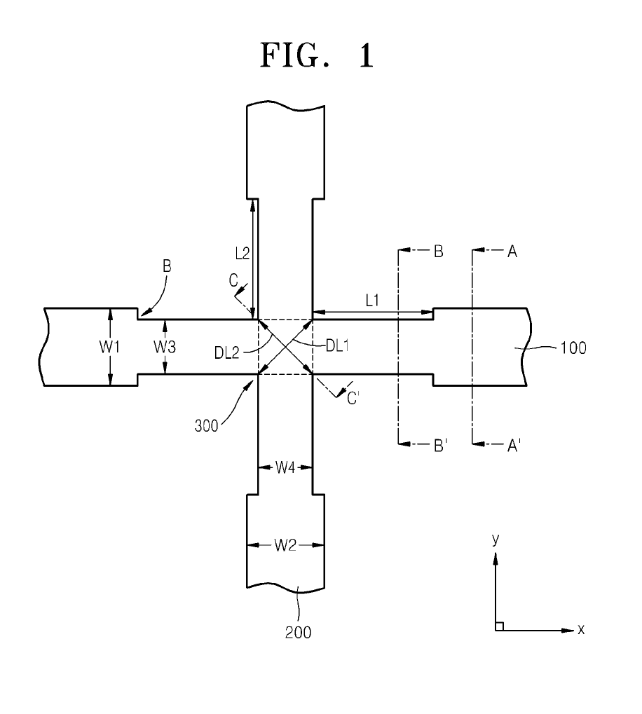

FIG. 1 is a plan view of a wiring structure of a semiconductor device, according to example embodiments of the inventive concepts.

Referring to FIG. 1, a first wiring 100 and a second wiring 200 that intersect each other are provided. In example embodiments, the first wiring 100 may extend in a first direction (x-direction of FIG. 1) and the second wiring 200 may extend in a second direction (y-direction of FIG. 1). In example embodiments, the first wiring may have a first width W1 and the second wiring 200 may have a second width W2. In the present specification, unless specially mentioned, the first direction and the second direction are used as terms that also mean directions opposite to the x-direction and the y-direction that form an angle of 180° therewith, as well as the x-direction and the y-direction.

A portion in which the first wiring 100 and the second wiring 200 intersect each other is a rectangular region and is referred to as an intersecting region 300 in the present specification. The intersecting region 300 is a portion in which the first wiring 100 and the second wiring 200 intersect each other and may be defined as a region that is formed by extending the first wiring 100 and the second wiring 200 in a virtual manner and is surrounded by extension lines of the first wiring 100 and the second wiring 200. In example embodiments, the intersecting region 300 may have the shape of a rectangle. Diagonal lines DL1 and DL2 for connecting two facing vertexes may be defined in the intersecting region 300.

In the first wiring 100, the intersecting region 300 and a portion that corresponds to a first length L1 from the intersecting region 300 in the first direction (x-direction of FIG. 1) may have a third width W3 that is smaller than the first width W1. In the second wiring 200, the intersecting region 300 and a portion that corresponds to a second length L2 from the intersecting region 300 in the second direction (y-direction of FIG. 1) may have a fourth width W4 that is smaller than the second width W2.

A central line of the third width W3 and a central line of the fourth width W4 may coincide with a central line of the first width W1 of the first wiring 100 and a central line of the second width W2 of the second wiring 200, respectively. In other words, the first width W1 and the second width W2 are reduced to the same width in upward and downward directions so that the first wiring 100 having the third width W3 and the second wiring 200 having the fourth width W4 can be formed. Thus, a bending portion B for reducing line widths of the first and second wirings 100 and 200 may be formed between the first width W1 and the third width W3 and the second width W2 and the fourth width W4, respectively. Two bending portions B may be formed on both side surfaces of the first and second wirings 100 and 200. For example, in example embodiments, the first wiring 100 may have a pair of bending portions B formed on each of the right and left sides of the intersecting region 300.

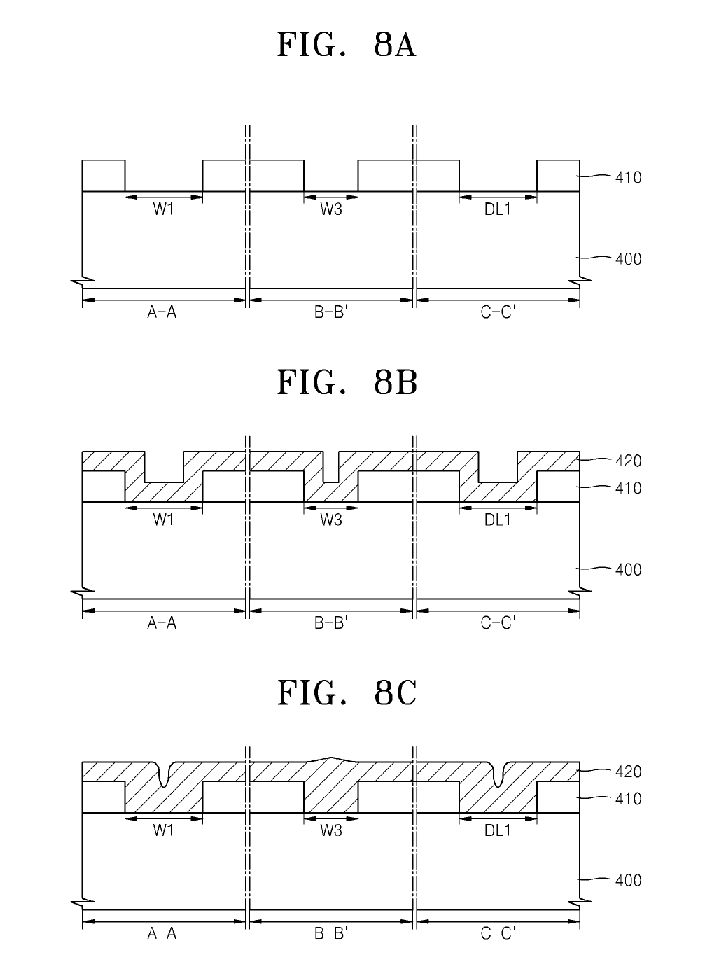

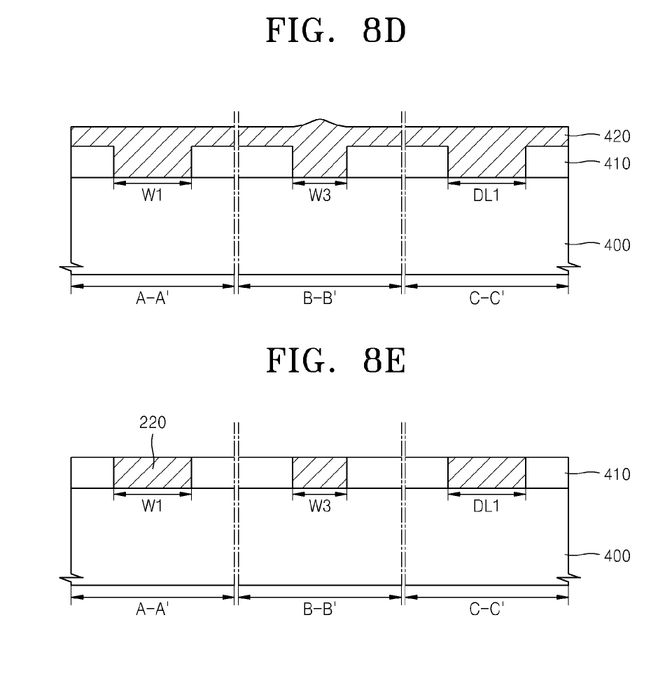

Each of the third width W3 and the fourth width W4 may be a value obtained by reducing each of the first width W1 and the second width W2 by a ratio. In example embodiments, the ratio that may or may not be predetermined. For example, each of the third width W3 and the fourth width W4 may have a dimension that is 0.7 to 0.9 times of each of the first width W1 and the second width W2, for example, 0.8 times of each of the first width W1 and the second width W2. Each of the third width W3 and the fourth width W4 may be determined in such a way that the length of a diagonal line that is relatively large between diagonal lines DL1 and DL2 of the intersecting region 300 may have a dimension in a similar range to a relatively large value of the first width W1 and the second width W2, for example, a dimension that is 0.8 to 1.2 times of the first width W1 and the second width W2, so as to prevent defects from occurring in a process of fabricating the first and second wirings 100 and 200 and to improve efficiency of the process. This will be described later in detail with reference to FIGS. 8A through 8E.

For example, when the third width W3 and the fourth width W4 have the same dimension, i.e., a dimension ‘a·W1’ that is obtained by reducing each of the first width W1 and the second width W2 by a predetermined ratio, the intersecting region 300 is a quadrangle including four sides having the length of a·W1. Thus, the diagonal lines DL1 and DL2 each have the length of \sqrt{2}a·W1. If lengths of the diagonal lines DL1 and DL2 are equal to W1, a should be

$$\frac{1}{\sqrt{2}} .$$

As a result, the third width W3 and the fourth width W4 may be determined to have a similar value to

$$\frac{1}{\sqrt{2}}$$

·W1 that 15 about 0.7 to 0.9 times of the first width W1.

The first length L1 and the second length L2 may be defined in the range of a minimum value and a maximum value. In example embodiments, the minimum and maximum values may or may not be predetermined. Defining of the minimum value means that the first and second wirings 100 and 200 should have the third width W3 and the fourth width W4 reduced by a length (noting the length may or may not be predetermined), so as to improve efficiency of the process of fabricating the first and second wirings 100 and 200. The minimum value may be 0.3 to 0.5 times of each of the first width W1 and the second width W2. The maximum value is defined to prevent resistances of the first and second wirings 100 and 200 from being increased when a section where the first and second wirings 100 and 200 have reduced widths W3 and W4 is increased. In addition, the maximum value is defined so as to minimize or reduce the amount of a wiring material that is deposited on the first and second wirings 100 and 200 and to be removed from the first and second wirings 100 and 200 by performing a planarization process in the process of fabricating the first and second wirings 100 and 200 that will be described later in detail with reference to FIGS. 8A through 8E. The maximum value may be about 10 to 15 times of each of the first width W1 and the second width W2.

The first wiring 100 and the second wiring 200 may be formed of a conductive material. The first wiring 100 and the second wiring 200 may include at least one metal selected from the group comprising copper (Cu), tungsten (W), aluminum (Al), molybdenum (Mo), titanium (Ti), tantalum (Ta), and ruthenium (Ru), for example. In addition, the first wiring 100 and the second wiring 200 may have a multi-layer structure including a diffusion barrier layer (not shown).

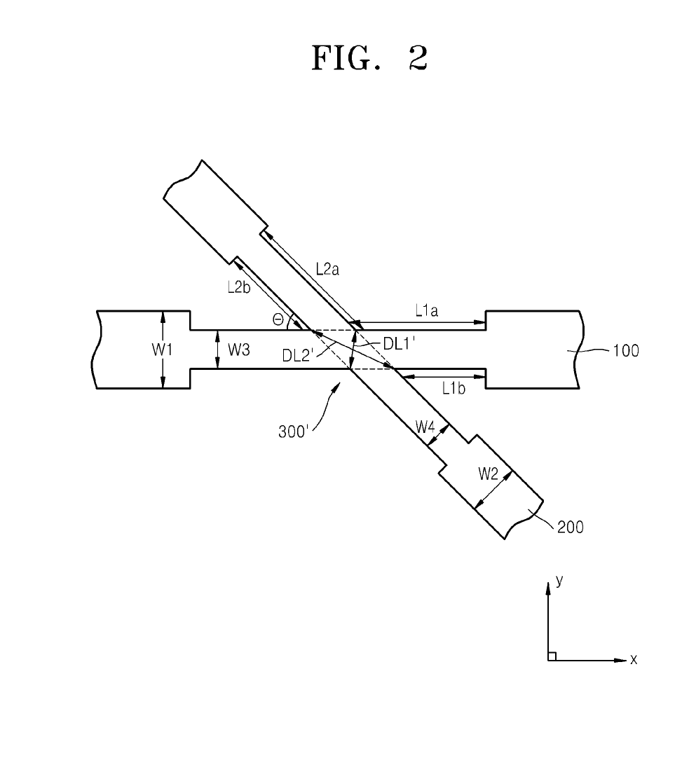

FIG. 2 is a plan view of a wiring structure of a semiconductor device, according to example embodiments of the inventive concepts. In FIG. 2, the same reference numerals as those of FIG. 1 denote the same elements, and thus a repeated description thereof will not be provided here.

Referring to FIG. 2, a first wiring 100 and a second wiring 200 that intersect each other are provided. The first wiring 100 has a first width W1 and extends in a first direction (x-direction of FIG. 1). The second wiring 200 has a second width W2 that is smaller than the first width W1 and extends while forming an angle θ with the first wiring 100. In example embodiments, the angle θ may or may not be predetermined. For example, in example embodiments the angle θ may be a predetermined acute angle.

In example embodiments, an intersection region 300′ in which the first wiring 100 and the second wiring 200 intersect each other may have the shape of a parallelogram.

In the first wiring 100, the intersecting region 300′ and a portion that corresponds to predetermined lengths L1a and L1b from the intersecting region 300′ in the first direction (x-direction of FIG. 1) may have a third width W3 that is smaller than the first width W1. The lengths L1a and L1b may be different from each other on different side surfaces of the first wiring 100. In example embodiments, the lengths L1a and L1b may also be equal to each other. In the second wiring 200, a portion that corresponds to lengths L2a and L2b from the intersecting region 300′ may have a fourth width W4 that is smaller than the second width W2. The lengths L2a and L2b may be different from each other on different side surfaces of the second wiring 200. In example embodiments, the lengths L2a and L2b may also be equal to each other.

Each of the third width W3 and the fourth width W4 may be a value obtained by reducing each of the first width W1 and the second width W2 by a ratio that may or may not be predetermined. For example, each of the third width W3 and the fourth width W4 may have a dimension that is 0.7 to 0.9 times of each of the first width W1 and the second width W2. Each of the third width W3 and the fourth width W4 may be determined in such a way that the length of a diagonal line DL2′ that is relatively large between diagonal lines DL1′ and DL2′ of the intersecting region 300′ may have a dimension in a similar range to the first width W1.

For example, when each of the third width W3 and the fourth width W4 has a dimension obtained by reducing each of the first width W1 and the second width W2 by a ratio ‘a’, the length of the diagonal line DL2′ is proportional to \sqrt{a²W1²+a²W2²+2a²W1·W2·cos θ}, and a value a that makes the value equal to W1 is proportional to

$$\frac{W 1}{\sqrt{W {1}^{2} + 2 W 1 \cdot W 2 \cdot cos θ + W {2}^{2}}} .$$

Thus, the value a may vary according to the size of the angle θ. The value a may be selected in a similar range to a calculated value. For example, each of the third width W3 and the fourth width W4 may have a value between about 0.5 to 0.9 times of the first width W1 and the second width W2 according to the size of the angle θ.

The lengths L1a, L1b, L2a, and L2b may have a minimum value and a maximum value. In example embodiments, the lengths L1a, L1b, L2a, and L2b may or may not be predetermined. The minimum value may be a dimension that is 0.3 to 0.5 times of each of the first width W1 and the second width W2. The maximum value may be a dimension that is about 10 to 15 times of each of the first width W1 and the second width W2.

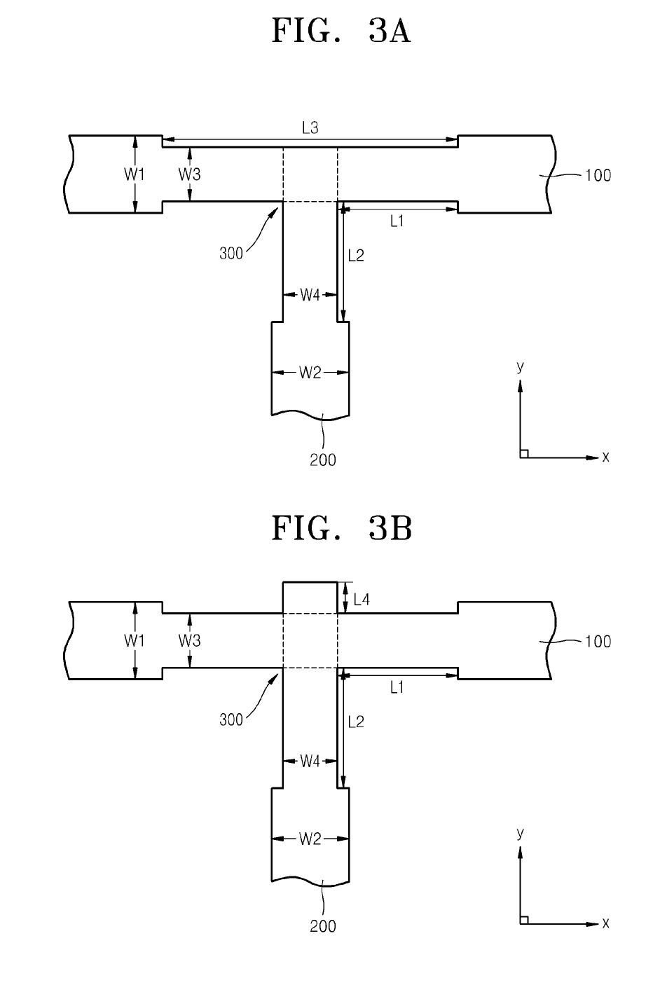

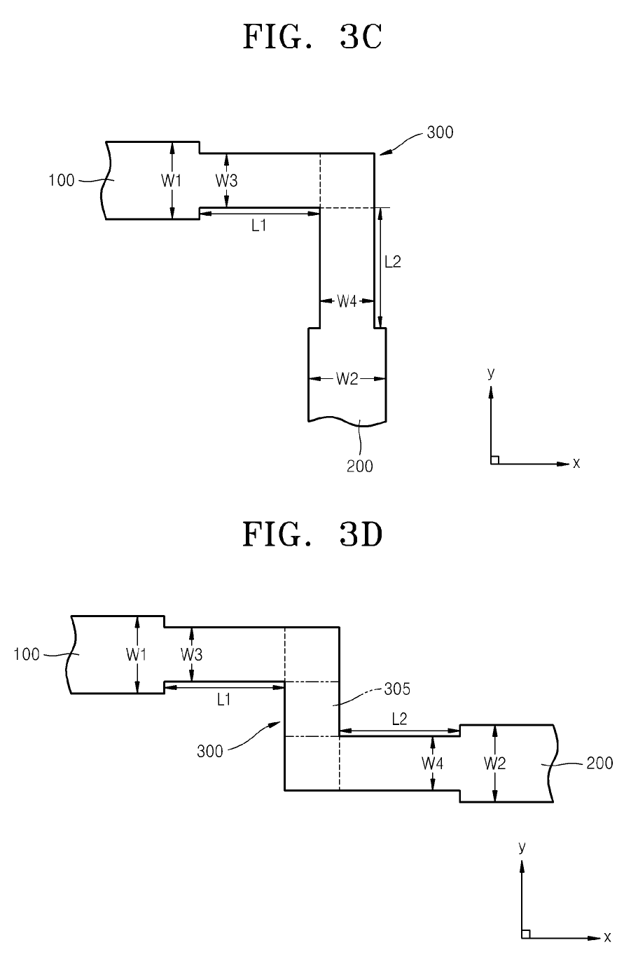

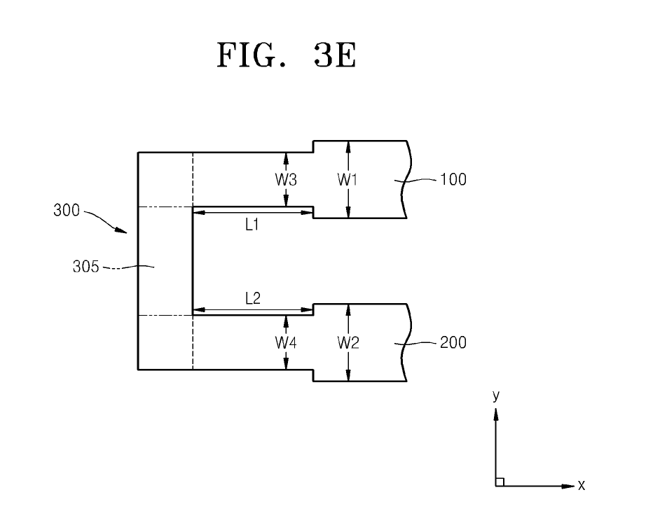

FIGS. 3A through 3E are plan views of wiring structures of semiconductor devices, according to example embodiments of the inventive concepts. In FIGS. 3A through 3E, the same reference numerals as those of FIGS. 1 and 2 denote the same elements, and thus a repeated description thereof will not be provided here.

Referring to FIG. 3A, a first wiring 100 that has a first width W1 and extends in a first direction (x-direction of FIG. 1), and a second wiring 200 that has a second width W2, intersects the first wiring 100 and extends in a second direction (y-direction of FIG. 1), are provided. The second wiring 200 extends from an intersecting region 300 only in a one direction.

In the first and second wirings 100 and 200, the intersecting region 300 and a portion that corresponds to a first length L1 and a second length L2 from the intersecting region 300 may have a third width W3 that is smaller than the first width W1 and a fourth width W4 that is smaller than the second width W2. In addition, in a direction in which the second wiring 200 does not extend, the first wiring 100 may have the third width W3 with respect to a third length L3 that is larger than the first length L1.

Each of the third width W3 and the fourth width W4 may have a dimension obtained by reducing each of the first width W1 and the second width W2 by a ratio that may or may not be predetermined.

Referring to FIG. 3B, a similar wiring structure to a wiring structure of FIG. 3A is provided. The difference between the wiring structures of FIGS. 3A and 3B is that a second wiring 200 extends in a one direction from the interesting region 300 by a fourth length L4. The fourth length L4 to be extended may have the fourth width W4.

Referring to FIG. 3C, a first wiring 100 that has a first width W1 and extends in a first direction (x-direction of FIG. 1), and a second wiring 200 that has a second width W2 intersects the first wiring 100 and extends in a second direction (y-direction of FIG. 1), are provided. Each of the first wiring 100 and the second wiring 200 extends from an intersecting region 300 only in a one direction.

In the first and second wirings 100 and 200, the intersecting region 300 and a portion that corresponds to a first length L1 and a second length L2 from the intersecting region 300 may have a third width W3 that is smaller than the first width W1 and a fourth width W4 that is smaller than the second width W2. Each of the third width W3 and the fourth width W4 may correspond to a dimension obtained by reducing each of the first width W1 and the second width W2 by a ratio that may or may not be predetermined.

The intersecting region 300 is defined by extension lines of the first wiring 100 and the second wiring 200. In the intersecting region 300, the first wiring 100 extends with the third width W3, and the second wiring 200 extends with the fourth width W4.

Referring to FIG. 3D, a first wiring 100 and a second wiring 200 are provided. The first wiring 100 and the second wiring 200 have a first width W1 and extend in a first direction (x-direction of FIG. 1). The first wiring 100 and the second wiring 200 extend to form an angle of 180° with each other and extend from the intersecting region 300 only in a one direction. The first wiring 100 and the second wiring 200 are parallel to each other and are connected to each other due to the intersecting region 300.

In example embodiments, the intersecting region 300 may include a vertical connection portion 305. The intersecting region 300 connects the first wiring 100 and the second wiring 200 due to the vertical connection portion 305 that is perpendicular to the first wiring 100 and the second wiring 200 in addition to the extension lines of the first wiring 100 and the second wiring 200.

In the first and second wirings 100 and 200, the intersecting region 300 and a portion that corresponds to a first length L1 and a second length L2 may have a third width W3 that is smaller than the first width W1 and a fourth width W4 that is smaller than the second width W2. The vertical connection portion 305 may have the same width as the third width W3 or the fourth width W4. Each of the third width W3 and the fourth width W4 may be a dimension obtained by reducing each of the first width W1 and the second width W2 by a ratio that may or may not be predetermined.

Referring to FIG. 3E, a first wiring 100 and a second wiring 200 are provided. The first wiring 100 and the second wiring 200 have a first width W1 and a second width W2 and the first wiring 100 and the second wiring 200 may extend in a first direction (x-direction of FIG. 1) to the same length L1 and L2. In FIG. 3E, the first width W1 and the second width W2 may be equal. Each of the first wiring 100 and the second wiring 200 extends from the intersecting region 300 only in a one direction. The first wiring 100 and the second wiring 200 may be parallel to each other and may be connected to each other due to the intersecting region 300.

In example embodiments, the intersecting region 300 may include a vertical connection portion 305. The intersecting region 300 connects the first wiring 100 and the second wiring 200 due to the vertical connection portion 305 that is perpendicular to the first wiring 100 and the second wiring 200 in addition to the extension lines of the first wiring 100 and the second wiring 200.

In the first and second wirings 100 and 200, the intersecting region 300 and a portion that corresponds to a first length L1 and a second length L2 from the intersecting region 300 may have a third width W3 that is smaller than the first width W1 and a fourth width W4 that is smaller than the second width W2. The vertical connection portion 305 may have the same width as the third width W3 or the fourth width W4. Each of the third width W3 and the fourth width W4 may be a dimension obtained by reducing each of the first width W1 and the second width W2 by a ratio that may or may not be predetermined.

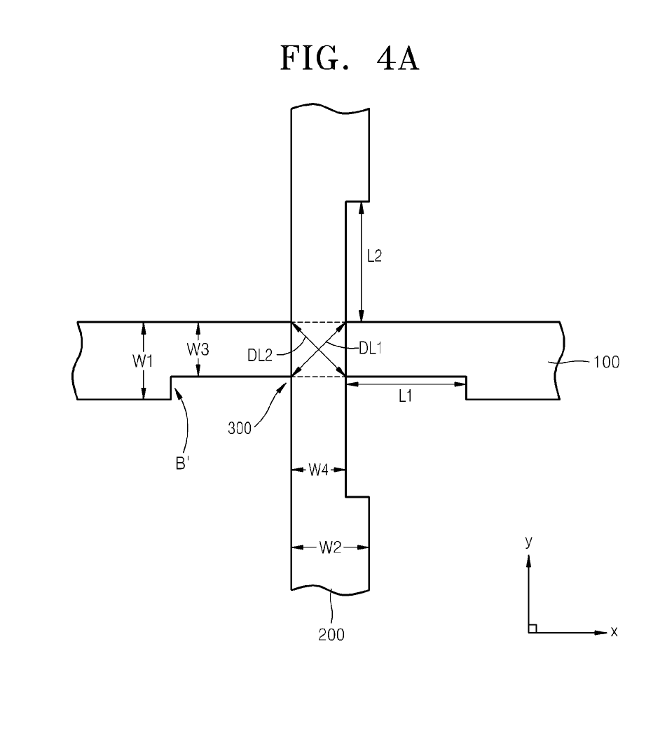

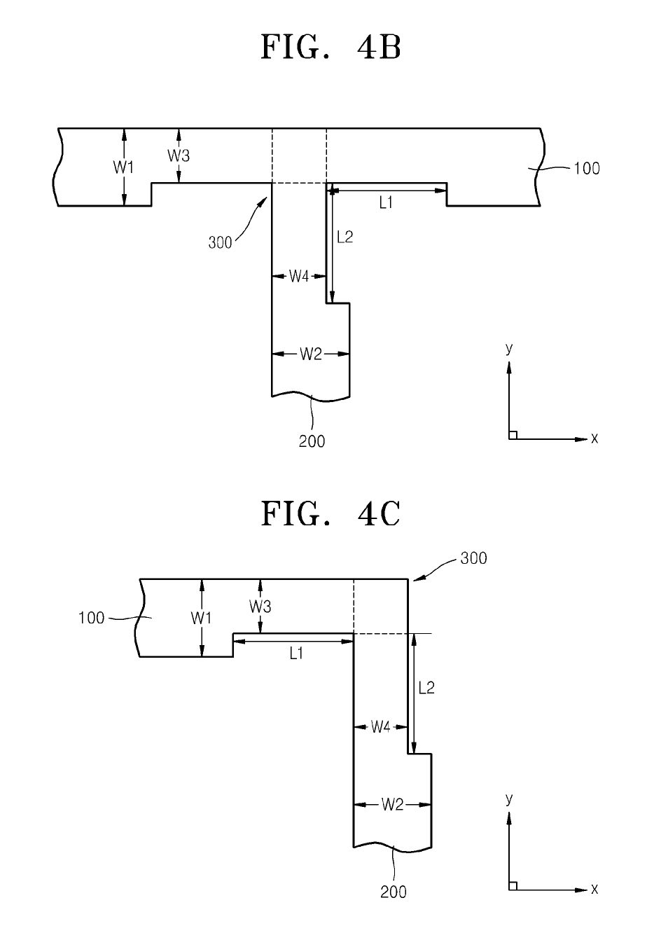

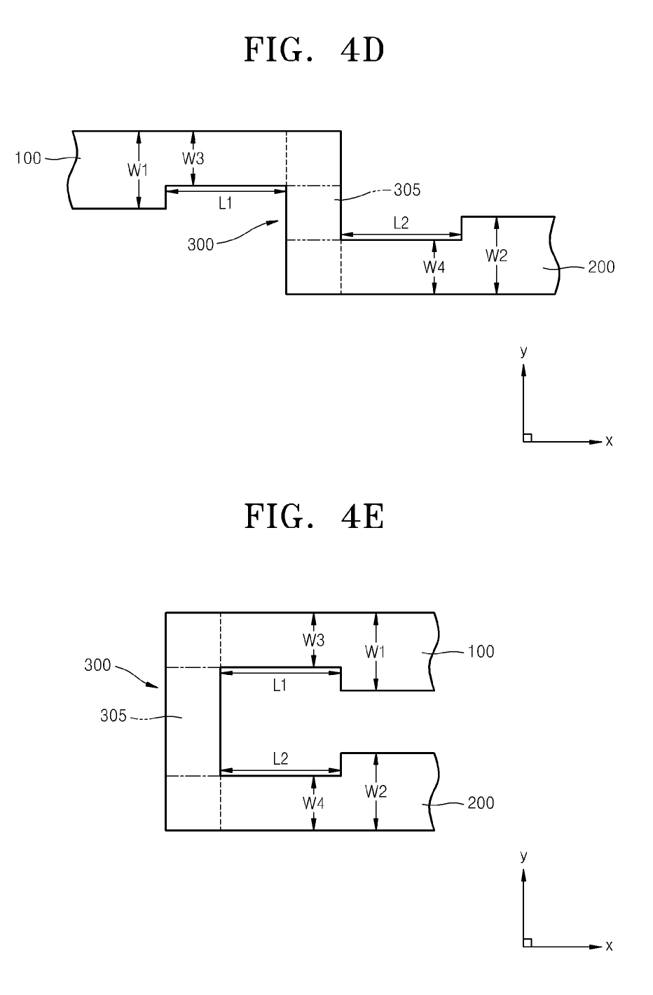

FIGS. 4A through 4E are plan views of wiring structures of semiconductor devices, according to example embodiments of the inventive concepts. In FIGS. 4A through 4E, the same reference numerals as those of FIGS. 1 through 3E denote the same elements, and thus a repeated description thereof will not be provided here.

Referring to FIG. 4A, a first wiring 100 that has a first width W1 and extends in a first direction (x-direction of FIG. 1), and a second wiring 200 that has a second width W2 intersects the first wiring 100 and extends in a second direction (y-direction of FIG. 1), are provided.

In the first and second wirings 100 and 200, an intersecting region 300 and a portion that corresponds to a first length L1 and a second length L2 from the intersecting region 300 may have a third width W3 that is smaller than the first width W1 and a fourth width W4 that is smaller than the second width W2.

In example embodiments, one side surface of the portion having the third width W3 and the fourth width W4 may coincide with one side surface of a portion having the first width W1 of the first wiring 100 and the second width W2 of the second wiring 200. In other words, on the other side surface of the portion having the first width W1 and the second width W2, each of the first width W1 and the second width W2 may be reduced to a width so that the first and second wirings 100 and 200 having the third width W3 and the fourth width W4 can be formed. In example embodiments, the width may or may not be predetermined. Thus, a bending portion B′ for reducing the first and second wirings 100 and 200 may be formed between the first width W1 and the third width W3 and between the second width W2 and the fourth width W4. One bending portion B′ may be formed on one side surface of each of the first and second wirings 100 and 200. For example, in example embodiments, the first wiring 100 may have one bending portion B′ on each of the right and left sides of the intersecting region 300.

Each of the third width W3 and the fourth width W4 may have a value obtained by reducing each of the first width W1 and the second width W2 by a ratio that may or may not be predetermined. For example, each of the third width W3 and the fourth width W4 may have a dimension that is 0.7 to 0.9 times of each of the first width W1 and the second width W2. Each of the third width W3 and the fourth width W4 may be determined in such a way that the length of a diagonal line that is relatively large between diagonal lines DL1 and DL2 of the intersecting region 300 may have a dimension in a similar range to a relatively large value of the first width W1 and the second width W2.

The first length L1 and the second length L2 may be determined in the range of a minimum value and a maximum value. In example embodiments, the minimum value and the maximum value may or may not be predetermined. The minimum value may be a dimension that is 0.3 to 0.5 times of each of the first width W1 and the second width W2. The maximum value may be a dimension that is about 10 to 15 times of each of the first width W1 and the second width W2.

Referring to FIG. 4B, a first wiring 100 that has a first width W1 and extends in a first direction (x-direction of FIG. 1), and a second wiring 200 that has a second width W2 intersects the first wiring 100 and extends in a second direction (y-direction of FIG. 1), are provided. The second wiring 200 extends from an intersecting region 300 only in a one direction.

In the first and second wirings 100 and 200, the intersecting region 300 and a portion that corresponds to a first length L1 and a second length L2 from the intersecting region 300 may have a third width W3 that is smaller than the first width W1 and a fourth width W4 that is smaller than the second width W2.

Each of the third width W3 and the fourth width W4 may be a dimension obtained by reducing each of the first width W1 and the second width W2 by ratio that may or may not be predetermined. One side surface of the portion having the third width W3 and the fourth width W4 may coincide with one side surface of a portion having the first width W1 of the first wiring 100 and the second width W2 of the second wiring 200. In other words, on the other side surface of the portion having the first width W1 and the second width W2, each of the first width W1 and the second width W2 may be reduced to a width (where the width may or may not be predetermined) so that the first and second wirings 100 and 200 having the third width W3 and the fourth width W4 can be formed.

Referring to FIG. 4C, a first wiring 100 that has a first width W1 and extends in a first direction (x-direction of FIG. 1), and a second wiring 200 that has a second width W2 intersects the first wiring 100 and extends in a second direction (y-direction of FIG. 1), are provided. Each of the first wiring 100 and the second wiring 200 extends from an intersecting region 300 only in a one direction.

In the first and second wirings 100 and 200, the intersecting region 300 and a portion that corresponds to a first length L1 and L2 from the intersecting region 300 may have a third width W3 that is smaller than the first width W1 and a fourth width W4 that is smaller than the second width W2.

Each of the third width W3 and the fourth width W4 may be a dimension obtained by reducing each of the first width W1 and the second width W2 by a ratio that may or may not be predetermined. One side surface of the portion having the third width W3 and the fourth width W4 may coincide with one side surface of a portion having the first width W1 of the first wiring 100 and the second width W2 of the second wiring 200. In other words, on the other side surface of the portion having the first width W1 and the second width W2, each of the first width W1 and the second width W2 may be reduced to a width (where the width may or may not be predetermined) so that the first and second wirings 100 and 200 having the third width W3 and the fourth width W4 can be formed. In example embodiments, each of the first and second wirings 100 and 200 may have a shape reduced on one side surface of each of the first and second wirings 100 and 200, for example, on the lower side surface of the first wiring 100 and on the right side surface of the second wiring 200. However, the inventive concepts are not limited to this, and each of the first and second wirings 100 and 200 may have a shape reduced on the upper side surface of the first wiring 100 and the left side surface of the second wiring 200.

Referring to FIG. 4D, a first wiring 100 and a second wiring 200 are provided. The first wiring 100 and the second wiring 200 have a first width W1 and a second width W2 and the second width W2 may be equal to the first width W1. In example embodiments, the first wiring 100 and the second wiring 200 may extend in a first direction (x-direction of FIG. 1). For example, in FIG. 4D, the first wiring 100 and the second wiring 200 extend to form an angle of 180° with each other and extend from the intersecting region 300 in a first direction. In example embodiments, the first wiring 100 and the second wiring 200 are parallel to each other and are connected to each other due to the intersecting region 300.

In example embodiments, the intersecting region 300 may include a vertical connection portion 305. The intersecting region 300 may connect the first wiring 100 and the second wiring 200 due to the vertical connection portion 305 in addition to the extension lines of the first wiring 100 and the second wiring 200.

In the first and second wirings 100 and 200, the intersecting region 300 and a portion that corresponds to a first length L1 and a second length L2 from the intersecting region 300 may have a third width W3 that is smaller than the first width W1 and a fourth width W4 that is smaller than the second width W2. Each of the third width W3 and the fourth width W4 may be a dimension obtained by reducing each of the first width W1 and the second width W2 by a ratio that may or may not be predetermined.

One side surface of a portion having the third width W3 and the fourth width W4 may coincide with one side surface of a portion having the first width W1 and the second width W2 of the first wiring 100 and the second wiring 200. In other words, on the other side surface of the portion having the first width W1 and the second width W2, each of the first width W1 and the second width W2 may be reduced to a width (where the width may or may not be predetermined) so that the first and second wirings 100 and 200 having the third width W3 and the fourth width W4 can be formed. In example embodiments, each of the first and second wirings 100 and 200 may have a shape reduced on one side surface of each of the first and second wirings 100 and 200, for example, on the lower side surface of the first wiring 100 and on the upper side surface of the second wiring 200. However, the inventive concepts are not limited to this, and each of the first and second wirings 100 and 200 may have a shape reduced on the upper side surface of the first wiring 100 and the lower side surface of the second wiring 200.

Referring to FIG. 4E, a first wiring 100 and a second wiring 200 are provided. The first wiring 100 and the second wiring 200 have a first width W1 and a second width W2. In example embodiments, the first width W1 and the second width W2 may be equal. In example embodiments, the first wiring 100 and the second wiring may extend in a first direction (x-direction of FIG. 1) to the same length. Each of the first wiring 100 and the second wiring 200 extends from the intersecting region 300 only in a one direction. The first wiring 100 and the second wiring 200 may be parallel to each other and may be connected to each other due to an intersecting region 300.

In example embodiments, the intersecting region 300 may include a vertical connection portion 305. The intersecting region 300 may connect the first wiring 100 and the second wiring 200 due to the vertical connection portion 305 that is perpendicular to the first wiring 100 and the second wiring 200 in addition to the extension lines of the first wiring 100 and the second wiring 200.

In the first and second wirings 100 and 200, the intersecting region 300 and a portion that corresponds to a first length L1 and a second length L2 from the intersecting region 300 may have a third width W3 that is smaller than the first width W1 and a fourth width W4 that is smaller than the second width W2. Each of the third width W3 and the fourth width W4 may be a dimension obtained by reducing each of the first width W1 and the second width W2 by a ratio that may or may not be predetermined.

One side surface of a portion having the third width W3 and the fourth width W4 may coincide with one side surface of a portion having the first width W1 and the second width W2 of the first wiring 100 and the second wiring 200. In other words, on the other side surface of the portion having the first width W1 and the second width W2, each of the first width W1 and the second width W2 may be reduced to a width (where the width may or may not be predetermined) so that the first and second wirings 100 and 200 having the third width W3 and the fourth width W4 can be formed. In example embodiments, each of the first and second wirings 100 and 200 may have a shape reduced on one side surface of each of the first and second wirings 100 and 200, for example, on the lower side surface of the first wiring 100 and on the upper side surface of the second wiring 200. However, the inventive concepts are not limited to this, and each of the first and second wirings 100 and 200 may have a shape reduced on the upper side surface of the first wiring 100 and the lower side surface of the second wiring 200.

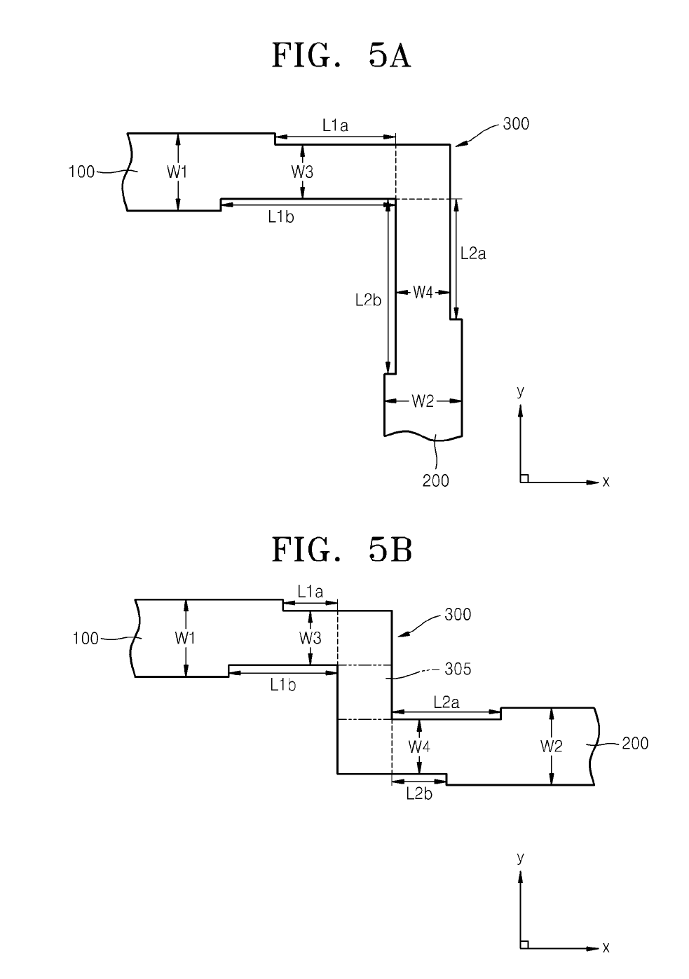

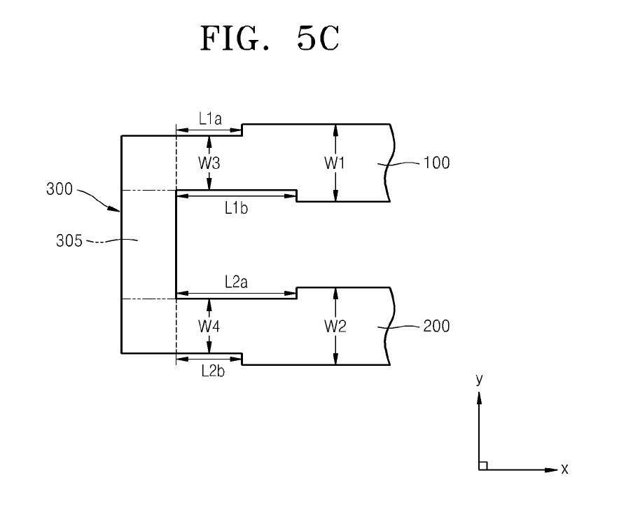

FIGS. 5A through 5C are plan views of wiring structures of semiconductor devices, according to example embodiments of the inventive concepts. In FIGS. 5A through 5C, the same reference numerals as those of FIGS. 1 through 4E denote the same elements, and thus a repeated description thereof will not be provided here.

Referring to FIG. 5A, a first wiring 100 that has a first width W1 and extends in a first direction (x-direction of FIG. 1), and a second wiring 200 that has a second width W2 intersects the first wiring 100 and extends in a second direction (y-direction of FIG. 1), are provided. Each of the first wiring 100 and the second wiring 200 extends from an intersecting region 300 only in a one direction.

In the first wiring 100, the intersecting region 300 and a portion that corresponds to first lengths L1a and L1b from the intersecting region 300 in the first direction (x-direction of FIG. 1) may have a third width W3 that is smaller than the first width W1. In the second wiring 200, the intersecting region 300 and a portion that corresponds to second lengths L2a and L2b from the intersecting region 300 in the second direction (y-direction of FIG. 1) may have a fourth width W4 that is smaller than the second width W2. Each of the third width W3 and the fourth width W4 may be a dimension obtained by reducing each of the first width W1 and the second width W2 by a predetermined ratio.

In the first wiring 100, the first lengths L1a and L1b may be different from each other on both side surfaces of the first wiring 100. When the length of an upper portion of the intersecting region 300 is added to the length L1a of an upper portion of the first wiring 100, the total length may be the same as the length L1b of a lower portion of the first wiring 100. In the second wiring 200, the second lengths L2a and L2b may be different from each other on both side surfaces of the second wiring 200. When the length of the right side of intersecting region 300 is added to the length L2a of the right side of the second wiring 200, the total length may be the same as the length L2b of the left side of the second wiring 200.

Referring to FIG. 5B, a first wiring 100 and a second wiring 200 are provided. The first wiring 100 and the second wiring 200 have a first width W1 and a second width W2 and the first wiring 100 and the second wiring 200 extend in a first direction (x-direction of FIG. 1). In example embodiments, the first width W1 and the second width W2 may be equal to one another. The first wiring 100 and the second wiring 200 extend from an intersecting region 300 only in a one direction while forming an angle of 180° with each other. The first wiring 100 and the second wiring 200 are parallel to each other and are connected to each other due to the intersecting region 300 including a vertical connection portion 305.

In the first wiring 100, the intersecting region 300 and a portion that corresponds to predetermined lengths L1a and L1b from the intersecting region 300 in the first direction (x-direction of FIG. 1) may have a third width W3 that is smaller than the first width W1. In the second wiring 200, a portion that corresponds to predetermined lengths L2a and L2b from the intersecting region 300 in the first direction (x-direction of FIG. 1) may have a fourth width W4 that is smaller than the second width W2. In the first wiring 100, the lengths L1a and L1b may be different from each other on both side surfaces of the first wiring 100. When the length of an upper portion of the intersecting region 300 is added to the length L1a of an upper portion of the first wiring 100, the total length may be the same as the length L1b of a lower portion of the first wiring 100. In the second wiring 200, the lengths L2a and L2b may be different from each other on the upper and lower portions of the second wiring 200. When the length of the lower portion of the intersecting region 300 is added to the length L2b of the lower portion of the second wiring 200, the total length may be the same as the length L2a of the upper portion of the second wiring 200.

Referring to FIG. 5C, the first wiring 100 and the second wiring 200 are provided. The first wiring 100 and the second wiring 200 have the first width W1 and a second width W2 and the first wiring 100 and the second wiring 200 extend in the first direction (x-direction of FIG. 1) to the same length. In example embodiments, the first width W1 and the second width W2 may be equal. Each of the first wiring 100 and the second wiring 200 extends from the intersecting region 300 only in a one direction. The first wiring 100 and the second wiring 200 are parallel to each other and are connected to each other due to an intersecting region including a vertical connection portion 305.

In the first wiring 100, the intersecting region 300 and a portion that corresponds to lengths L1a and L1b (where the lengths L1a and L1b may or may not be predetermined) from the intersecting region 300 in the first direction (x-direction of FIG. 1) may have a third width W3 that is smaller than the first width W1. In the second wiring 200, a portion that corresponds to lengths L2a and L2b (where the lengths L2a and L2b may or may not be predetermined) in the first direction (x-direction of FIG. 1) from the intersection region 300 may have a fourth width W4 that is smaller than the second width W2. In the first wiring 100, the lengths L1a and L1b may be different from each other on both side surfaces of the first wiring 100. When the length of the upper portion of the intersecting region 300 is added to the length L1a of the upper portion of the first wiring 100, the total length may be the same as the length L1b of the lower portion of the first wiring 100. In the second wiring 200, the lengths L2a and L2b may be different from each other on both side surfaces of the second wiring 200. When the length of the lower portion of the intersecting region 300 is added to the length L2b of the lower portion of the second wiring 200, the total length may be the same as the length L2a of the upper portion of the second wiring 200.

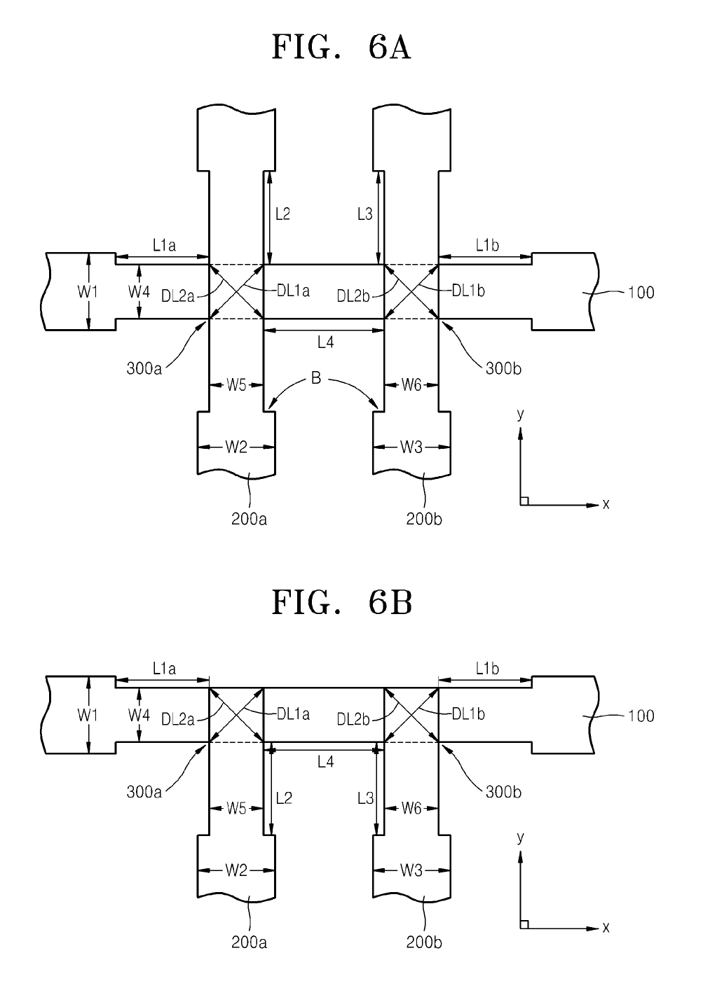

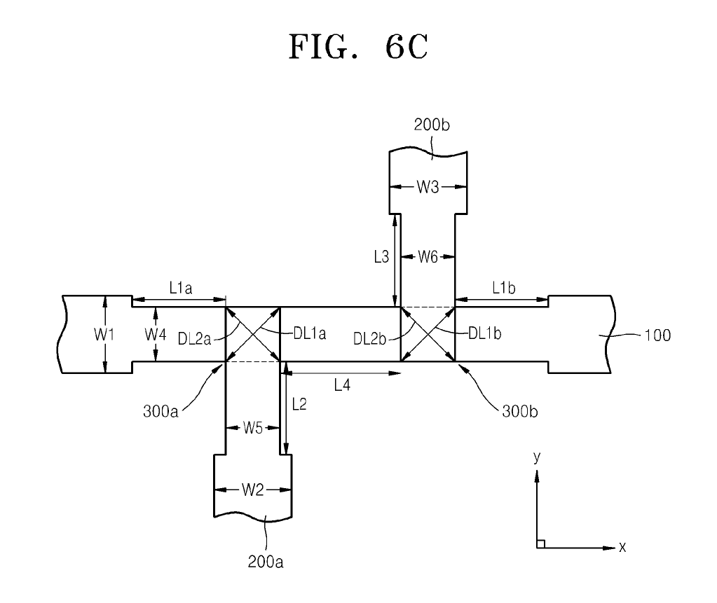

FIGS. 6A through 6C are plan views of wiring structures of semiconductor devices, according to example embodiments of the inventive concepts.

Referring to FIG. 6A, a first wiring 100 and second wirings 200a and 200b, which intersect one another, are provided. The first wiring 100 having a first width W1 extends in a first direction (x-direction of FIG. 1). The second wirings 200a and 200b each having a second width W2 and a third width W3 extend in a second direction (y-direction of FIG. 1).

Intersecting regions 300a and 300b are formed in a portion where the first wiring 100 and the second wirings 200a and 200b intersect one another. In example embodiments, the intersecting regions 300a and 300b may have the shape of a rectangle. Diagonal lines DL1a, DL1b, DL2a, and DL2b for connecting two facing vertexes may be defined in the intersecting regions 300a and 300b.

In the first wiring 100, a portion that corresponds to predetermined lengths L1a and L1b in the first direction (x-direction of FIG. 1) from the intersecting regions 300a and 300b and a portion that corresponds to a length L4 between the intersecting regions 300a and 300b may have a fourth width W4 that is smaller than the first width W1. In the second wirings 200a and 200b, portions that respectively correspond to predetermined lengths L2 and L3 from the intersecting regions 300a and 300b in the second direction (y-direction of FIG. 1) may have a fifth width W5 that is smaller than the second width W2 and a sixth width W6 that is smaller than the third width W3.

Each of the fourth width W4, the fifth width W5, and the sixth width W6 may have a value obtained by reducing each of the first width W1, the second width W2, and the third width W3 by a ratio that may or may not be predetermined. Thus, a bending portion B for reducing line widths of the first wiring 100 and the second wirings 200a and 200b may be formed between the first width W1 and the fourth width W4, between the second width W2 and the fifth width W5, and between the third width W3 and the sixth width W6, respectively.

Each of the fourth width W4, the fifth width W5, and the sixth width W6 may have a dimension that is 0.7 to 0.9 times of each of the first width W1, the second width W2, and the third width W3. Each of the fourth width W4, the fifth width W5, and the sixth width W6 may be determined in such a way that a diagonal line having the largest length among diagonal lines DL1a, DL1b, DL2a, and DL2b of the intersecting regions 300 and 300b may have a dimension in a similar range to one width having the largest value among the fourth width W4, the fifth width W5, and the sixth width W6, so as to prevent defects from occurring in a process of fabricating the first wiring 100 and the second wirings 200a and 200b and to improve efficiency of the process. This will be described later in detail with reference to FIGS. 8A through 8E.

The lengths L1a, L1b, L2, and L3 may be determined in the range of a minimum value and a maximum value. In example embodiments, the lengths L1a, L1b, L2, and L3 and the minimum value and the maximum value may or may not be predetermined. The minimum value may be defined because the first wiring 100 and the second wirings 200a and 200b should have the fourth width W4, the fifth width W5, and the sixth width W6 reduced to a length (where the length may or may not be predetermined) so as to improve efficiency of the process of fabricating the first wiring 100 and the second wirings 200a and 200b. The minimum value may be a dimension that is 0.3 to 0.5 times of each of the first width W1, the second width W2, and the third width W3. The maximum value is defined to prevent resistances of the first wiring 100 and the second wirings 200a and 200b from being increased when a section where the first wiring 100 and the second wirings 200a and 200b have reduced widths W4, W5, and W6 is increased. The maximum value may be a dimension that is about 10 to 15 times of each of the first width W1, the second width W2, and the third width W3.

Referring to FIGS. 6B and 6C, a first wiring 100 and second wirings 200a and 200b, which intersect one another, are provided. The first wiring 100 having a first width W1 extends in a first direction (x-direction of FIG. 1). The second wirings 200a and 200b each having a second width W2 and a third width W3 extend in a second direction (y-direction of FIG. 1). The second wirings 200a and 200b extend from the intersecting regions 300a and 300b parallel to only a one direction. In the embodiment of FIG. 6B, the second wirings 200a and 200b extend in the same direction, and in the embodiment of FIG. 6C, the second wirings 200a and 200b extend to form an angle of 180° with each other.

The lengths L2 and L3 from the intersecting regions 300a and 300b may be equal to each other according to sizes of the second width W2 and the third width W3. Alternatively, the lengths L2 and L3 may be different from each other in proportion to the second and third widths W2 and W3. In example embodiments, the lengths L2 and L3 may or may not be predetermined.

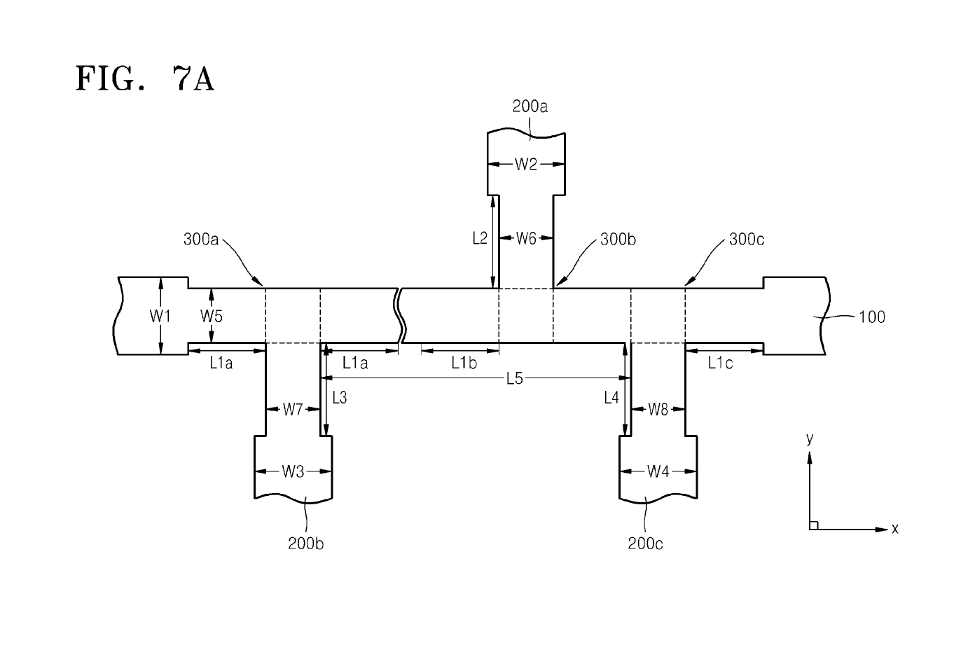

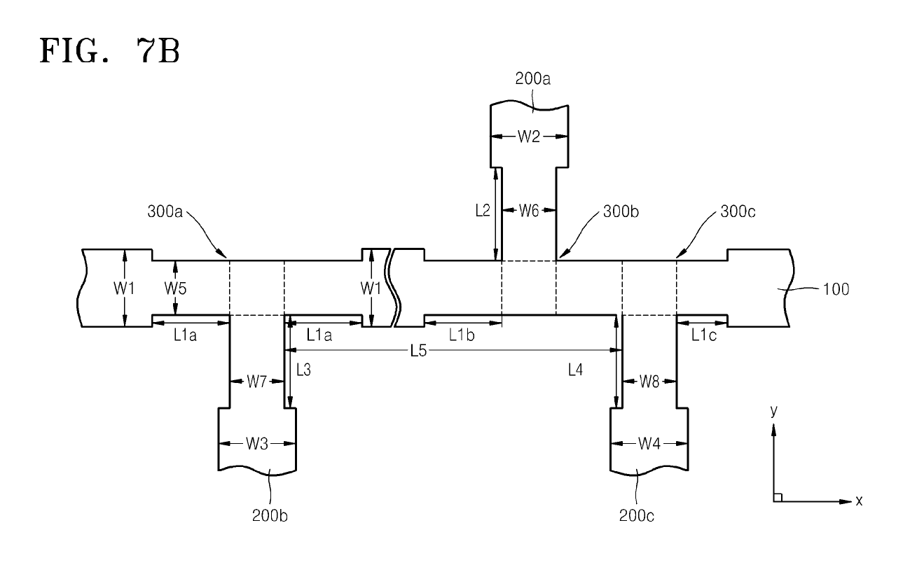

FIGS. 7A and 7B are plan views of wiring structures of semiconductor devices, according to example embodiments of the inventive concepts.

Referring to FIG. 7A, a first wiring 100 and second wirings 200a, 200b, and 200c, which intersect one another, are provided. The first wiring 100 having a first width W1 extends in a first direction (x-direction of FIG. 1). The second wirings 200a, 200b, and 200c each having the second width W2, the third width W3, and the fourth width W4 extend in the second direction (y-direction of FIG. 1).

In the first wiring 100, a portion that corresponds to lengths L1a, L1b, and L1c from intersecting regions 300a, 300b, and 300c in the first direction (x-direction of FIG. 1), the intersecting regions 300a, 300b, and 300c, and a portion that corresponds to a length L5 between the intersecting regions 300a and 300c may have a fifth width W5 that is smaller than the first width W1. In the second wirings 200a, 200b, and 200c, portions that correspond to lengths L2, L3, and L4 from the intersecting regions 300a, 300b, and 300c in the second direction (y-direction of FIG. 1) may have a sixth width W6, a seventh width W7, and an eighth width W8, which are smaller than the second width W2, the third width W3, and the fourth width W4, respectively. Each of the fifth through eighth widths W5 through W8 may have a value obtained by reducing each of the first through fourth widths W1 through W4 by a ratio that may or may not be predetermined. In example embodiments, the lengths L1a, L1b, L1c, L2, L3, and L4 may or may not be predetermined.

The lengths L1a, L1b, L1c, L2, L3, and L4 may be different from one another and may be determined in the range of a minimum value and a maximum value. In example embodiments, the minimum and maximum values may or may not be predetermined. The maximum value may be a dimension that is about 10 to 15 times of each of the first through fourth widths W1 through W4. In this case, when a length L5 between the second wirings 200b and 200c that extend in the same direction is a dimension that is about 10 to 15 times of the first width W1, the first wiring 100 may extend with the fifth width W5.

Referring to FIG. 7B, when the length L5 between the second wirings 200b and 200c that extend in the same direction is a dimension that is above 10 to 15 times of the first width W1, the first wiring 100 may have a line width of the first width W1 after distances L1a and L1b from the intersecting regions 300a and 300b adjacent to the first wiring 100. The first wiring 100 may also have a line width of the first width W1 after distances L1a and L1b from the intersecting regions 300b and 300c adjacent to the first wiring 100.

FIGS. 8A through 8E are cross-sectional views for explaining a method of fabricating a wiring structure of a semiconductor device, according to example embodiments of the inventive concepts. FIGS. 8A through 8E are cross-sectional views taken along lines A-A′, B-B′, and C-C′ of FIG. 1.

Referring to FIG. 8A, an insulating layer pattern 410 is formed on a substrate 400. Referring to FIG. 8A with reference to FIG. 1, the insulating layer pattern 410 is formed to have a first width W1, a third width W3, and a length corresponding to a length of a diagonal line DL1. The insulating layer pattern 410 may be formed by performing an etching process. The etching process may be performed by an additional etch stop layer (not shown).

The substrate 400 may include a semiconductor material, such as a Group IV semiconductor, a Group III-IV compound semiconductor or a Group II-VI oxide semiconductor. For example, the Group IV semiconductor may include silicon (Si), germanium (Ge) or silicon-germanium (SiGe). Although not shown, the substrate 400 may include an element (not shown) of a semiconductor device, for example, a gate.

The insulating layer pattern 410 may be formed of a low-k dielectric material. The low-k dielectric material may have a dielectric constant that is less than about 4. The low-k dielectric material may be silicon carbide (SiC), silicon oxide (SiO₂), fluoridated silicon oxide films (SiOF) or fluoridated oxide. Alternatively, the low-k dielectric material may include a doped oxide, for example, hydrogen silsesquioxane (HSQ), fluorinated silicate glass (FSG) or methyl silsesquioxane (MSQ), or a porous material, such as aerogel.

Referring to FIG. 8B, a wiring layer 420 is stacked on the insulating layer pattern 410. As illustrated in FIG. 8B, the wiring layer 420 is deposited along the insulating layer pattern 410 to a uniform width.

The wiring layer 420 may include a conductive material. The wiring layer 420 may include one from among at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), a metal alloy, a conductive metal oxide, a conductive polymer material, and a conductive composite material. The wiring layer 420 may be deposited using physical vapor deposition (PVD), chemical vapor deposition (CVD) or atomic layer deposition (ALD).

A lower side of the wiring layer 420 may include a diffusion barrier layer (not shown). The diffusion barrier layer (not shown) may be at least one metal nitride selected from the group consisting of titanium nitride (TiN), titanium nitride/tungsten (TiN/W), titanium/titanium nitride (Ti/TiN), tungsten nitride (WN), tungsten/tungsten nitride (W/WN), tantalum nitride (TaN), tantalum/tantalum nitride ((Ta/TaN), titanium silicon nitride (TiSiN), tantalum silicon nitride (TaSiN), and tungsten silicon nitride (WSiN). The diffusion barrier layer (not shown) may be deposited using CVD, ALD or PVD including sputtering.

Referring to FIG. 8C, deposition of the wiring layer 420 is further performed. Since the third width W3 is smaller than the first width W1 and the diagonal line DL1, an area having a width corresponding to the third width W3, of the wiring layer 420 is filled with a conductive material used to form the wiring layer 420, and an area having a width corresponding to dimensions of the first width W1 and the diagonal line DL1, of the wiring layer 420 has not completely been deposited.

Referring to FIG. 8D, deposition of the wiring layer 420 has been completely performed. The area having a width corresponding to dimensions of the first width W1 and the diagonal line DL1, of the wiring layer 420 is also filled with a conductive material. A convex portion may be formed in the center of the area having the width corresponding to the third width W3 due to a deposited material.

Referring to FIG. 8E, the wiring layer 420 may be removed from the upper side of the insulating layer pattern 410. This process is a process of planarizing the wiring layer 420 so that the wiring layer 420 may remain only in the insulating layer pattern 410. The process may be performed using chemical mechanical polishing (CMP). As a result, a wiring structure of a semiconductor device according to example embodiments of the inventive concepts is fabricated.

In the wiring structure of the semiconductor device according to example embodiments of the inventive concepts, a line width is reduced from the intersecting region 300 in which the first wiring 100 and the second wiring 200 of FIG. 1 intersect each other so that the wiring layer 420 may be deposited seamlessly on a cross-section taken along the diagonal line DL1 of the intersecting region 300. In addition, since the length of the diagonal line DL1 and the dimension of the first width W1 are similar to each other, the wiring layer 420 may be formed by using material with a minimum quantity used to form the wiring layer 420 to be deposited on the insulating layer pattern 410 and to be removed therefrom by using CMP. Thus, efficiency of the process of fabricating the first and second wirings 100 and 200 may be improved.

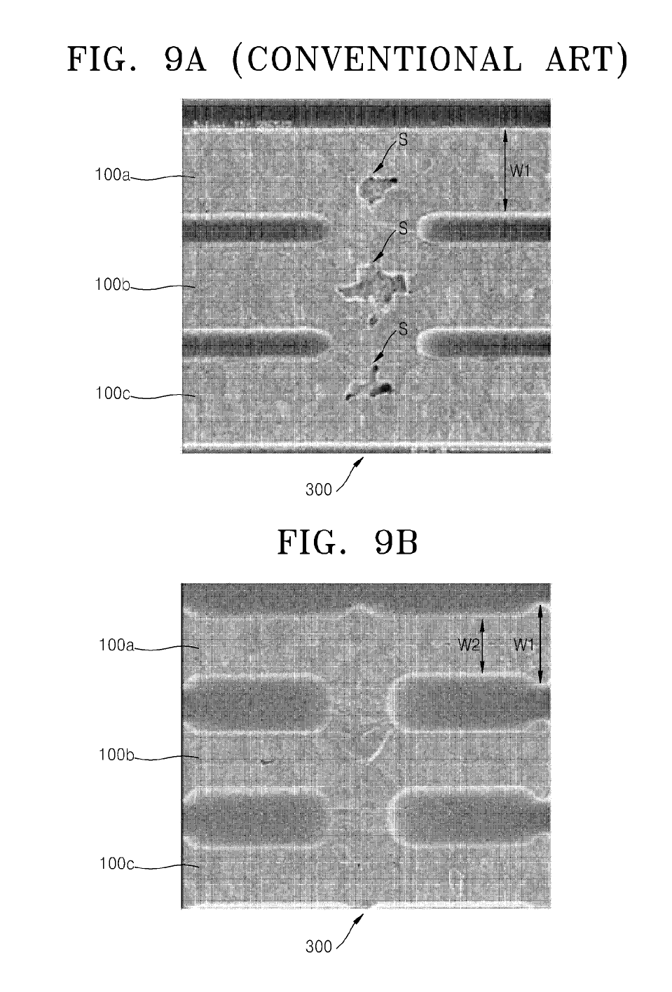

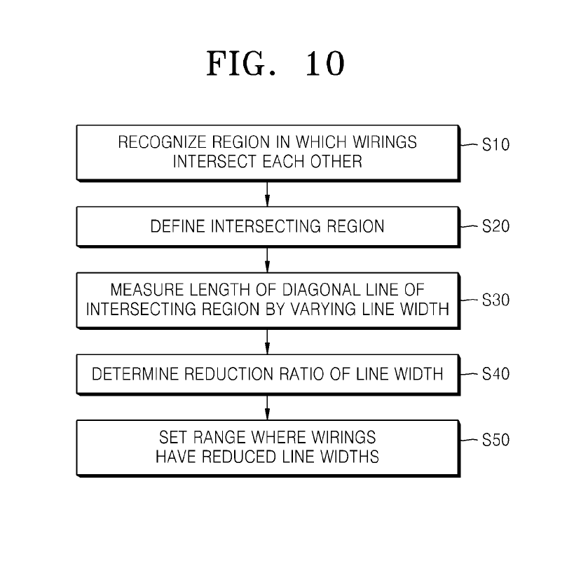

FIGS. 9A and 9B are electron microscope photos for illustrating a wiring structure of a semiconductor device, according to example embodiments of the inventive concepts.

Referring to FIGS. 9A and 9B, the wiring structure is analyzed using scanning electron microscopy (SEM). In the wiring structure, three wirings 100a, 100b, and 100c are connected to one another through an intersecting region 300.

Referring to FIG. 9A, the wirings 100a, 100b, and 100c are formed to the same first width W1. Referring to FIG. 9B, which illustrates a wiring structure according to example embodiments of the inventive concepts, the wirings 100a, 100b, and 100c have a second width W2 that is smaller than the first width W1 with respect to a predetermined distance from the intersecting region 300. Seams S illustrated in FIG. 9A are not generated in the wiring structure according to example embodiments of the inventive concepts. Thus, the wiring structure may be formed by depositing a wiring material with a minimum quantity.

FIG. 10 is a flowchart illustrating a layout method of forming a wiring structure of a semiconductor device, according to example embodiments of the inventive concepts.

Referring to FIG. 10, in operation S10, for the layout of the wiring structure, a region in which wirings intersect each other is recognized. Operation S10 corresponds to an operation of reading a region in which two or more wirings intersect each other, from layout data of a conventional wiring structure.

In operation S20, an intersecting region is defined in the region in which wirings intersect each other recognized in operation S10. The intersecting region may be defined as a closed curve to be defined by the wirings or extension lines thereof in the region in which the wirings intersect each other. The closed curve means a closed region. In the present specification, the closed curve is used in wider senses regardless of whether lines forming the closed curve are straight or curved lines. When intersecting wirings are parallel to each other, as illustrated in FIGS. 3D and E, the intersecting region is defined by including a vertical connection portion parallel to the wiring layer.

In operation S30, a length of a diagonal line of the intersecting region is measured by varying line widths of the wirings. By continuously reducing line widths of the wirings from their original line widths by a ratio, the length of the diagonal line of the intersecting region corresponding to the reduced line widths of the wirings may be measured. In this case, the length of the diagonal line of the intersecting region may be measured by reducing two or more intersecting wirings by a ratio that may or may not be predetermined. For example, the length of the diagonal line of the intersecting region may be measured by reducing the line widths of the wirings from 0.9 times of their original line widths continuously by 0.01 times of the original line widths. The diagonal line means the longest line from among lines for connecting two arbitrary points in the intersecting region. When the intersecting region is a circle, the diagonal line may correspond to a diameter of the circle. When the intersecting region is a polygon, the diagonal line may correspond to the longest line from among lines for connecting two arbitrary angles.

In operation S40, the length of the diagonal line is compared with the original line widths of the wirings and thereby a reduction ratio of a line width corresponding to a value that makes the length of the diagonal line be most similar to the original line widths of the wirings is determined. In operation S40, the length of the diagonal line is varied according to the reduction ratio of the line width, and a ratio at which the length of the diagonal line is most similar to the original line widths of the wirings is searched. Thus, the reduction ratio of the line width may be determined.

Last, in operation S50, a range where the wirings have the reduced line widths, is set. The wirings have the line widths reduced in the intersection region and from a length that extends from the intersecting region. The length may correspond to a length of 0.3 to 15 times of the original line widths from the intersecting region.

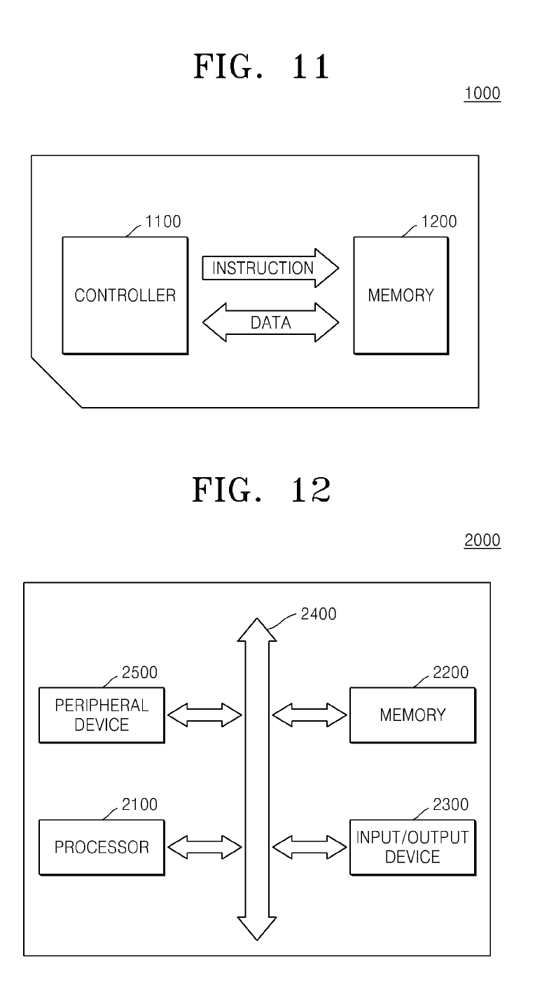

FIG. 11 is a schematic view of a memory card 1000 including a semiconductor device, according to example embodiments of the inventive concepts.

The memory card 1000 may be disposed in such a way that a controller 1100 and a memory 1200 exchange an electrical signal. For example, when the controller 1100 gives an instruction to the memory 1200, the memory 1200 may transmit data.

The memory 1200 may include semiconductor devices according to example embodiments of the inventive concepts. In particular, the memory 1200 may include a characteristic structure of at least one semiconductor device selected from the semiconductor devices illustrated in FIGS. 1 through 7B according to example embodiments of the inventive concepts.

The memory card 1000 may include a variety of cards, such as, a memory stick card, a smart media card (SM), a secure digital card (SD), a mini-secure digital card (mini SD), and a multimedia card (MMC).

FIG. 12 is a schematic view of a system 2000 including a semiconductor device, according to example embodiments of the inventive concepts.

In the system 2000, a processor 2100, a memory 2200, and an input/output device 2300 may perform data communication with one another by using a bus 2400.

The memory 2200 of the system 2000 may include a random access memory (RAM) and a read only memory (ROM). In addition, the system 2000 may include a peripheral device 2500, for example, a floppy disc drive or a compact disc (CD) ROM drive.

The memory 2200 may include semiconductor devices according to example embodiments of the inventive concepts. In particular, the memory 2200 may include a characteristic structure of at least one semiconductor device selected from the semiconductor devices illustrated in FIGS. 1 through 7B according to example embodiments of the inventive concepts.

The memory 2200 may store codes and data for operating the processor 2100.

The system 2000 may be used in a mobile phone, an MP3 player, a navigation device, a portable multimedia player (PMP), a solid state disc (SSD) or household appliances.

The foregoing is illustrative of example embodiments and is not to be construed as limiting thereof. Although example embodiments have been described, those of ordinary skill in the art will readily appreciate that many modifications are possible in example embodiments without materially departing from the novel teachings and advantages of the example embodiments. Accordingly, all such modifications are intended to be included within the scope of the claims. Example embodiments are defined by the following claims, with equivalents of the claims to be included therein.

What is claimed is:

1. A wiring structure of a semiconductor device, the wiring structure comprising:
a first wiring having a first width, the first wiring extending in a first direction; and
a second wiring electrically connected to the first wiring, the second wiring having a second width that is equal to or less than the first width, the second wiring extending in a second direction, wherein
the first wiring and the second wiring connect at an intersecting region,
the first wiring has a first portion extending from the intersecting region in the first direction,
the second wiring has a second portion extending from the intersection region in the second direction,
the first portion has a third width that is smaller than the first width, and
the second portion has a fourth width that is smaller than the second width.

2. The wiring structure of claim 1, wherein the intersecting region is a closed curve defined by an intersection of the first and second portions.

3. The wiring structure of claim 2, wherein a length of a largest straight line from among lines for connecting two arbitrary points on the closed curve forming the intersecting region is 0.8 to 1.2 times of the first width.

4. The wiring structure of claim 1, wherein a ratio of the third width to the first width is equal to a ratio of the fourth width to the second width.

5. The wiring structure of claim 1, wherein the third width is about 0.7 to about 0.9 times the first width and the fourth width is about 0.7 to about 0.9 times the second width.

6. The wiring structure of claim 1, wherein the first direction and the second direction are perpendicular to each other, and the first width and the second width are substantially the same.

7. The wiring structure of claim 1, wherein a length of the first portion is about 0.3 to about 0.5 times the first width and a length of the second portion is about 0.3 to about 0.5 times the second width.

8. The wiring structure of claim 1, wherein a length of the first portion is one of equal to and less than 10 times of the first width.

9. The wiring structure of claim 1, wherein the first wiring includes at least one bending portion between the first width and the third width and the second wiring includes at least one bending portion between the second width and the fourth width.

10. The wiring structure of claim 9, wherein,
when the first wiring includes two bending portions, the bending portions of the first wiring are in a straight line perpendicular to the first wiring and on different side surfaces of the first wiring, and
when the second wiring includes two bending portions, the bending portions of the second wiring are in a straight line perpendicular to the second wiring and on different side surfaces of the second wiring.

11. The wiring structure of claim 9, wherein
when the first wiring includes one bending portion, the bending portion of the first wiring is on one side surface of the first wiring, and
when the second wiring includes one bending portion, the bending portion of the second wiring is on one side surface of the first wiring.

12. The wiring structure of claim 1, wherein the first wiring or the second wiring extend from the intersecting region only in a one direction.

13. The wiring structure of claim 1, wherein
the first direction and the second direction are parallel to each other, and
the intersecting region comprises
a vertical connection portion that connects the first wiring to the second wiring, and the vertical connection portion is perpendicular to the first direction and the second direction, and
a region in which an extension line of the vertical connection portion and the first and second wirings intersect one another.

14. The wiring structure of claim 13, wherein the vertical connection portion has a width that is equal to one of the third width and the fourth width.

15. A wiring structure of a semiconductor device, the wiring structure comprising:
an intersecting region;
a first wiring extending from the intersecting region in a first direction and having a first width;
a second wiring extending from the intersecting region in a second direction and having a second width that is equal to or smaller than the first width,
wherein the first wiring has a third width that is smaller than the first width along a length from the intersecting region and the second wiring has a fourth width that is smaller than the second width along a length from the intersecting region.

16. A wiring structure of a semiconductor device, the wiring structure comprising:
an intersecting region;
a first wiring extending from the intersecting region, the first wiring including a first portion adjacent to the intersection region and a second portion extending from the first portion, the first portion having a first width and the second portion having a second width which is larger than the first width, the first and second portions extending in a first direction; and
a second wiring extending from the intersecting region, the second wiring including a third portion adjacent to the intersection region and a fourth portion extending from the first portion, the third portion having a third width and the fourth portion having a fourth width which is larger than the third width, the third and fourth portions extending in a second direction,
wherein a length of a largest straight line from among lines connecting two arbitrary points on the intersecting region is about 0.8 to about 1.2 times the second width and the fourth width.

17. The wiring structure of claim 1, wherein each of the second width and the fourth width has a dimension of about 0.7 to about 0.9 times of each of the first width and the third width.

18. The wiring structure of claim 1, wherein the first direction and the second direction are perpendicular to each other, and the second width and the fourth width are substantially the same.

19. The wiring structure of claim 1, wherein a length of the first portion is equal to or greater than 0.3 times of the first width and a length of the second portion is equal to or greater than 0.3 times the third width.

20. The wiring structure of claim 1, wherein a length of the first portion is equal to or less than 10 times of the second width and a length of the second portion is equal to or less than 10 times the fourth width.
